(19) United States
(12) Patent Application Publication
(10) Pub. No.: US 2019/0355783 A1
(43) Pub. Date: Nov. 21, 2019

(54) LED MODULE

(71) Applicant: SOLAR LUCE CO., LTD., Suwon-si (KR)

(72) Inventor: Jin Uk KOH, Suwon-si (KR)

(73) Assignee: SOLAR LUCE CO., LTD., Suwon-si (KR)

(21) Appl. No.: 16/479,173

(22) PCT Filed: Jan. 25, 2017
(86) PCT No.: PCT/KR2017/000852

§ 371 Date: Jul. 18, 2019

(51) Int. Cl. H01L 27/15; H01L 25/075; H01L 33/50; H01L 33/58

(52) U.S. Cl. CPC H01L 27/153; H01L 33/58; H01L 33/50; H01L 25/075

(57) ABSTRACT

The present invention provides an LED module which is easily manufactured and has thermal durability and excellent color reproducibility. An LED module according to an aspect of the present invention comprises a substrate; at least one LED bare chip mounted on the substrate; and at least one color conversion sheet formed on the LED bare chip and including a phosphor, in which the color conversion sheet is formed so as to cover at least one LED bare chip and a height of a region corresponding to the LED bare chip in the color conversion sheet is different from a height of a region not corresponding to the LED bare chip in the color conversion sheet.

### TECHNICAL FIELD

The present invention relates to an LED module, and more particularly, to an LED module for illumination in which a phosphor sheet is attached to an LED bare chip without using an LED package in which the LED bare chip is molded with a phosphor.

### BACKGROUND ART

A light emitting diode (LED) refers to an element that emits predetermined light by making a small number of injected carriers (electrons or holes) using a p-n junction structure of a semiconductor and recombining the carriers. In the LED, there are a red light emitting diode using GaAsP or the like, a green light emitting diode using GaP or the like, and a blue light emitting diode using an InGaN/AlGaN double hetero structure.

In particular, recent light emitting devices for illumination realize white light by combining a light emitting diode chip and a phosphor mold. For example, a phosphor is disposed on a light emitting diode chip that emits blue light to obtain white light by emitting blue light of the light emitting diode chip and yellow-green or yellow light of the phosphor. That is, a blue light emitting diode chip composed of a semiconductor component emitting a wavelength of 430 nm to 480 nm and a phosphor emitting yellow-green light and yellow light using blue light as excitation source are combined with each other to realize white light.

That is, up to now, a white light emitting device for illumination has used a method in which light having sufficiently high energy emitted from a blue LED bare chip of a high luminance is molded on the LED bare chip and a phosphor mold disposed thereon is excited to induce a white color.

However, to form the phosphor mold, a method of configuring a so-called LED package by installing a reflector and injecting a phosphor resin into the reflector is used. In such an LED package, it is continuously pointed out that there are problems that the cost is increased due to the complexity of the manufacturing process, and irregular light brightness, high defect rate of devices, and low color reproducibility are caused due to a mixing ratio of an epoxy resin or a silicone resin used for applying the phosphor, thermal instability of such resin, and irregular deposition of the phosphor upon curing.

### PRIOR ART DOCUMENT

ENCAPSULANT HAVING SPHERE WITH DIFFERENT HARDNESS AND LED PACKAGE USING THE SAME (Korean Patent Publication No. 10-2012-0131369, Dec. 5, 2012)

### DISCLOSURE

### Technical Problem

In order to solve the problems in the related art, an object of the present invention is to provide an LED module which is easily manufactured and has thermal durability and excellent color reproducibility.

However, other objects of the present invention are not limited to the objects described above, and other objects, which are not mentioned above, will be apparent to those skilled in the art from the following description.

### Technical Solution

According to an aspect of the present invention, an LED module comprises a substrate; at least one LED bare chip mounted on the substrate; and at least one color conversion sheet formed on the LED bare chip and including a phosphor, in which the color conversion sheet may be formed so as to cover at least one LED bare chip and a height of a region corresponding to the LED bare chip in the color conversion sheet may be different from a height of a region not corresponding to the LED bare chip in the color conversion sheet.

The LED module may further comprise at least one underfilling layer formed to fill a space between the LED bare chips on the substrate and cover the periphery of the LED bare chip, in which the color conversion sheet may be attached to an upper surface of the underfilling layer or an upper surface of the LED bare chip.

The color conversion sheet may be formed so that the region corresponding to the LED bare chip protrudes upward from the region not corresponding to the LED bare chip.

The LED module may further comprise at least one light diffusion adhesive layer formed to fill a space between the LED bare chips on the substrate and to cover the side surface of the LED bare chip or contact the upper surface of the LED bare chip, wherein a buffer space or a lead-in portion in which the light diffusion adhesive layer is led into the lower portion of the LED bare chip is formed between the color conversion sheet and the side surface of the LED bare chip.

The buffer space may be formed between the color conversion sheet and the side surface of the LED bare chip, and the buffer space may be formed by compressing the color conversion sheet onto the substrate.

The LED module may further comprise a light diffusion layer formed to fill a space between the LED bare chips on the substrate and formed to cover the side surface of the LED chip or contact the upper surface of the LED bare chip, in which the light diffusion layer may transmit the light emitted from the LED bare chip to a region which the color conversion sheet does not correspond to the LED bare chip.

The LED module may further comprise least one sheet block formed to fill a space between the LED bare chips on the substrate, in which a gap region may be formed between the sheet block and the LED bare chip.

A region of the color conversion sheet corresponding to the gap region may be formed with a protrusion inserted into the gap region.

The LED module may further comprise a light diffusion lens formed adjacent to the side surface of the LED bare chip on the substrate, in which in the color conversion sheet, the region corresponding to the LED bare chip and the region corresponding to the light diffusion lens may form a main light emitting region, and the regions not corresponding to the LED bare chip and the light diffusion lens may form a sub light emitting region in which light reached by the light diffusion lens is excited and emitted or moves into the color conversion sheet to be excited and emitted.

### Advantageous Effects

The LED module of the present invention has a color conversion sheet and does not have an LED package manufacturing process, so that the LED module can be manufactured more easily.

Further, since the color conversion sheet is provided instead of the phosphor mold, the phosphor mold is prevented from being deteriorated by heat so that a white color can be excellently reproduced.

In addition, since the underfilling layer being in contact with the side surface of the LED bare chip is formed, the heat generated from the LED bare chip may be efficiently emitted to prevent the color conversion sheet from being deteriorated.

In addition, since the light of the LED bare chip is transmitted to the side, shading of a region where the LED bare chip is not provided on the substrate may be remarkably reduced.

### DESCRIPTION OF DRAWINGS

FIG. 1 is a perspective view illustrating an LED module according to a first embodiment of the present invention.

FIG. 2 is a cross-sectional view illustrating the LED module according to the first embodiment of the present invention.

FIG. 3 is a view illustrating a process of manufacturing a color conversion sheet.

FIG. 4 is a cross-sectional view illustrating the LED module according to a second embodiment of the present invention.

FIG. 5 is a cross-sectional view illustrating the LED module according to a third embodiment of the present invention.

FIG. 6 is a cross-sectional view illustrating the LED module according to a fourth embodiment of the present invention.

FIG. 7 is a plan view illustrating the LED module according to a fifth embodiment of the present invention.

FIG. 8 is a cross-sectional view illustrating the LED module according to the fifth embodiment of the present invention.

FIG. 9 is a perspective view illustrating an LED module according to a sixth embodiment of the present invention.

FIG. 10 is a cross-sectional view illustrating the LED module according to the sixth embodiment of the present invention.

FIG. 11 is a cross-sectional view describing an operation of the LED module according to the sixth embodiment of the present invention.

### MODES OF THE INVENTION

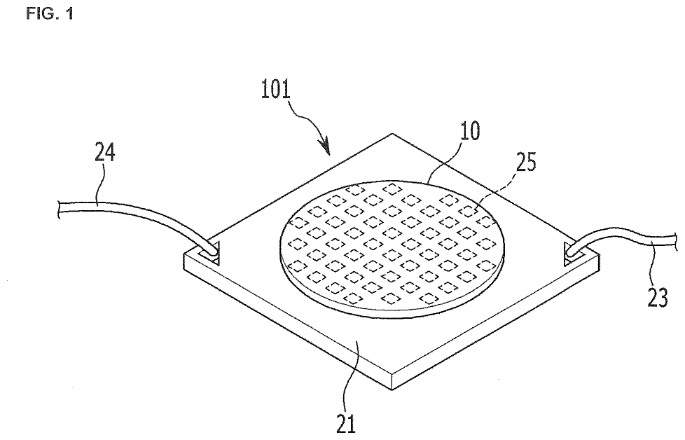

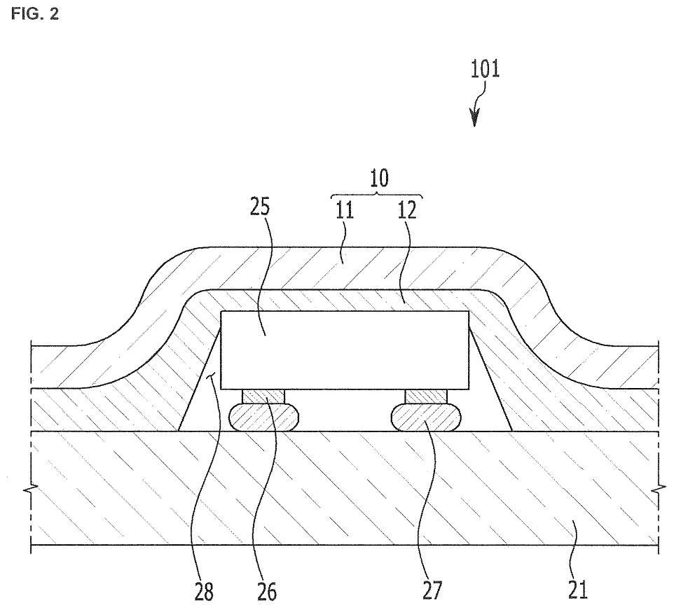

Hereinafter, the present invention and preferred embodiments of the present invention will be described in detail with reference to the accompanying drawings. FIG. 1 is a perspective view illustrating an LED module according to a first embodiment of the present invention and FIG. 2 is a cross-sectional view illustrating the LED module according to the first embodiment of the present invention.

Referring to FIGS. 1 and 2, an LED module 101 according to the first embodiment includes a substrate 21, an LED bare chip 25, and a color conversion sheet 10.

The substrate 21 can be any substrate that can mount the LED bare chip 25 at a high density. Although not limited, for example, such a substrate 21 may include alumina, quartz, calcium zirconate, forsterite, SIC, graphite, fused silica, mullite, cordierite, zirconia, beryllia, aluminum nitride, low temperature co-fired ceramic (LTCC), and the like.

The substrate 21 may be formed of a straight, circular or polygonal plate, and a first wire 23 and a second wire 24 for supplying power to the LED bare chip 25 are installed on the substrate 21. In the LED module 101 according to the first embodiment, the LED bare chip 25 and the substrate 21 are electrically connected with each other via a soldering portion 27 and the LED module 101 does not have a separate bonding wire. The soldering portion 27 electrically connects the LED bare chip 25 and the substrate 21 and particularly, electrically connects a terminal 26 formed on the LED bare chip 25 to the substrate 21. The soldering portion 27 may be formed by a surface mount technology (SMT).

The LED bare chip 25 is a blue light emitting LED chip, and may be made of a semiconductor component emitting a wavelength of 430 nm to 480 nm. However, the LED bare chip 25 may be an LED bare chip that emits different color light, and it is needless to say that the scope of the present invention is not limited to a specific LED bare chip. Meanwhile, the LED module according to the first embodiment of the present invention includes at least one LED bare chip. This is because the LED module according to this embodiment has a structure for an organic connection relationship of the LED bare chip 25 and the color conversion sheet 10, which are possible only in the LED module structure. Furthermore, although described in detail later, the LED module according to the first embodiment of the present invention is not a structure having a plurality of LED packages each in which a reflector is installed in a conventional LED bare chip and a phosphor molding layer is formed therebetween, but relates to a high-quality LED lighting module in which the LED package structure is avoided and the shading is removed according to the LED bare chip and the color conversion sheet 10 disposed thereon.

The color conversion sheet 10 is attached onto the LED bare chip 25 so as to cover the plurality of LED bare chips 25. One color conversion sheet 10 may be installed on the substrate 21 so as to cover all the LED bare chips 25 provided on the substrate 21. At this time, the color conversion sheet 10 may be formed of a unibody. However, the present invention is not limited thereto, and a plurality of color conversion sheets 10 may be provided in one substrate 21. However, even in the case, the color conversion sheet 10 may be provided so as to cover at least one LED bare chip 25.

At this time, when the force is applied to the substrate while the color conversion sheet 10 is attached, a height of the region corresponding to the LED bare chip 25 in the color conversion sheet 10 may be different from that of a region not corresponding to the LED bare chip 25 in the color conversion sheet 10. More specifically, the region corresponding to the LED bare chip 25 in the color conversion sheet 10 may be formed so as to protrude convexly above the region not corresponding to the LED bare chip 25.

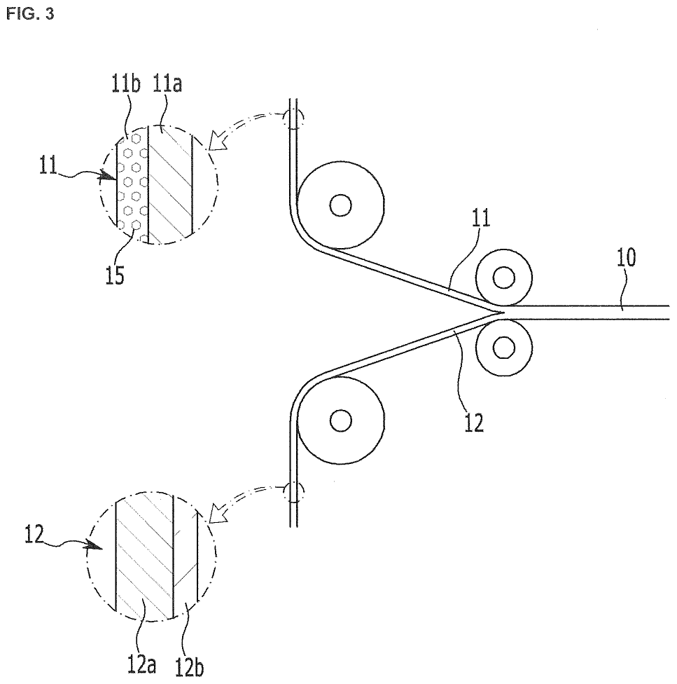

FIG. 3 is a view illustrating a process of manufacturing the color conversion sheet. As illustrated in FIG. 3, the color conversion sheet 10 may be formed by only a first sheet 11 having a phosphor 15, or may further include a second sheet 12 having an adhesive property. At this time, the second sheet 12 may serve as an underfilling layer, a light diffusion adhesive layer, a light diffusion layer, and the like, which will be described in detail in each embodiment.

The first sheet 11 includes a first substrate 11a and a phosphor layer 11b applied to the first substrate 11a. The first substrate 11a may be made of a resin, and the resin is not limited, but may include thermosetting resins having transparency such as a silicone resin, an epoxy resin, glass, a glass ceramic, a polyester resin, an acrylic resin, a urethane resin, a nylon resin, a polyamide resin, a polyimide resin, a vinyl chloride resin, a polycarbonate resin, a polyethylene resin, a teflon resin, a polystyrene resin, a polypropylene resin, and a polyolefin resin.

The phosphor layer 11b may be manufactured by using as a main component a phosphor which is excited by blue light emitted from the LED bare chip 25 to emit a wavelength of R or G series. Here, the present embodiment corresponds to a case where when the LED bare chip 25 outputs the blue light, the color conversion sheet 10 for making white light is constituted, but when the LED bare chip 25 outputs green light or red light, it is a matter of course that other phosphors may be used to make white light.

The phosphor layer 11b may be applied on the first substrate 11a in a printing method using a slot die or a doctor blade. At this time, the first sheet 11 is formed in the shape of a ribbon wound on a roller and may be conveyed at a speed of 1 m/min to 15 m/min, and the first sheet 11 is cured through a thermosetting section of 10 m or more.

The second sheet 12 includes a second substrate 12a and an adhesive layer 12b applied to the second substrate 12a. The second substrate 12a may be made of a resin having an adhesive force, and particularly heat-resistant transparent silicone. The adhesive layer 12b may include a transparent adhesive such as a UV curable resin, a thermosetting resin, and a sealant.

The adhesive layer 12b may be applied on the second substrate 12a in a printing method using a slot die or a doctor blade. The hardness of the second sheet 12 is formed to be smaller than the hardness of the first sheet 11 and the hardness of the second sheet 12 may be made to have a Shore A hardness of 5 or more and 20 or less. Further, the thickness of the second sheet 12 may be larger than 15 μm and smaller than the thickness of the LED bare chip 25. However, the present invention is not limited thereto, and the second sheet 12 may have various structures.

The second sheet 12 is formed to have greater thermal conductivity than the first sheet 11, and the second sheet 12 may be made of a polyimide resin and the second sheet 12 may include a metal oxide such as indium tin oxide (ITO) to improve thermal conductivity. Further, the first sheet 11 and the second sheet 12 may be pressurized and thermally adhered to each other by a roll-to-roll process.

Meanwhile, in the LED module according to the embodiment, a buffer space 28 may be formed between the color conversion sheet 10 and the side of the LED bare chip 25 by compressing the color conversion sheet 10 to the substrate in a direction of the LED bare chip 25. The height of the color conversion sheet 10 in the region corresponding to the LED bare chip 25 by the compression is at least equal to or larger than the height of the color conversion sheet 10 in the non-corresponding region. In other words, the region corresponding to the LED bare chip protrudes relatively upward, and the region not corresponding to the LED bare chip is formed so that concave and convex patterns relatively downward are alternately shown.

The buffer space 28 is formed to extend in a circumferential direction of the LED bare chip 25 and cover the side surface of the LED bare chip 25. In addition, the buffer space 28 may have a triangular channel shape and may have a triangular longitudinal section. According to the buffer space 28, the light emitted from the LED bare chip 25 is diffused in the buffer space 28, so that a dot appearance phenomenon may be further reduced.

Since the LED module 101 according to the first embodiment does not have the phosphor molding layer and is not formed in a package form and the LED bare chip 25 is directly mounted on the substrate 21, the volume of the LED modules may be significantly reduced and the manufacturing process may be significantly simplified. Further, since the color conversion sheet 10 instead of the phosphor molding layer is provided so as to cover the plurality of LED bare chips 25, the phosphor molding layer may be deteriorated due to an thermal influence to prevent the color reproducibility from being reduced and the buffer space is formed to further reduce the dot appearance phenomenon by diffusing the light emitted from the LED bare chip in the buffer space.

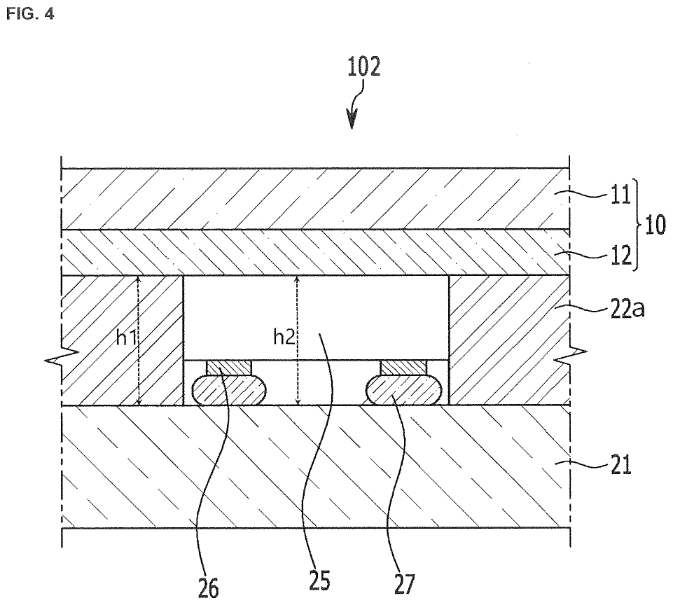

Hereinafter, a second embodiment of the present invention will be described. FIG. 4 is a cross-sectional view illustrating an LED module 102 according to a second embodiment of the present invention, and the same components as those of the first embodiment denote the same reference numerals and duplicated description of the same components is omitted.

The LED module 102 according to the second embodiment of the present invention further includes an underfilling layer 22a. The underfilling layer 22a is formed to fill a space between the LED bare chips 25 on the substrate and to cover the periphery of the LED bare chip. The underfilling layer 22a may be formed by attaching a sheet made of a film having elasticity to the substrate or by injecting a liquid resin between the LED bare chips 25. The underfilling layer 22a may also be made of at least one of an epoxy resin, a polyimide resin, a UV curable resin as a transparent adhesive component, a thermosetting resin, and a sealant.

In addition, the underfilling layer 22a may be formed of a light-transmitting material that transmits light and may be formed of a white or silver material that reflects light. One underfilling layer 22a is in contact with a side surface of the plurality of LED bare chips 25 to be formed of a unibody or a plurality of underfilling layers 22a may be formed individually on the substrate. That is, regardless of the size of the LED module, it is possible to provide a unit-sized underfilling layer and attach the underfilling layer to the LED module, thereby remarkably lowering the cost of a process of preparing the underfilling layer 22a.

The underfilling layer 22a is formed to cover the outer periphery of the LED bare chips 25. In this case, the underfilling layer 22a may be formed to be in contact with the side surface of the LED bare chip 25 while covering the periphery of the LED bare chip, or may be formed to be spaced apart from the side surface of the LED bare chip 25. When the underfilling layer 22a is formed to be in contact with the side surface of the LED bare chip 25, the underfilling layer 22a may be formed to be in contact with a part of the side surface, not the entire side surface. The reason is that as described later, when the adhesive layer of the color conversion sheet 10 performs the function of the underfilling layer 22a, if the color conversion sheet is compressed, the adhesive layer in a lower region of the side surface of the LED bare chip in the adhesive layer may have a buffer space due to the compression. Accordingly, when the underfilling layer 22a is formed to be in contact with the side surface of the LED bare chip 25, the underfilling layer 22a may be formed to be in contact with a part of the side surface, not the entire side surface.

A height h1 of an upper surface of the underfilling layer 22a may be equal to or larger than a height h2 of an upper surface of the LED bare chip 25. That is, the color conversion sheet 10 is attached by applying a pressure in a downward direction during attaching. In order to remove the shade, since it is preferable that the height of the color conversion sheet is flat in the entire area, the height h1 of the underfilling layer 22a disposed under the color conversion sheet 10 when the color conversion sheet 10 is compressed is preferably equal to or smaller than the height h2 of the LED bare chip 25. That is, the LED module according to the embodiment of the present invention is characterized in that the final thickness (height) of the underfilling layer is formed by compressing of the whole underfilling layer 10 to which the color conversion sheet 10 is attached.

Accordingly, a distance h1 between the upper surface of the underfilling layer 22a and the substrate 21 is equal to or smaller than a distance h2 between the upper surface of the LED bare chip 25 and the substrate 21. The underfilling layer 22a may be formed to expose only the upper surfaces of the LED bare chips 25 and cover the side surfaces and the lower surfaces of the LED bare chips 25.

As described above, the underfilling layer 22a serves not only to planarize a surface where the color conversion sheet 10 is attached so that the color conversion sheet 10 may be stably installed on the substrate 21, but also to rapidly emit heat generated by the LED bare chip 25 and the substrate 21.

Meanwhile, the color conversion sheet 10 is attached onto the upper surface of the LED bare chip 25 and the upper surface of the underfilling layer 22a so as to cover the plurality of LED bare chips 25. One color conversion sheet 10 is made of a unibody and covers all the LED bare chips 25 provided on the substrate 21 or a plurality of color conversion sheets 10 may be provided so as to cover at least one LED bare chip 25, rather than a unibody. However, even in the case, the plurality of color conversion sheets 10 may be provided so as to cover the plurality of LED bare chips 25. That is, regardless of the size of the LED module, it is possible to provide a color conversion sheet 10 of a unit size and separately attach the color conversion sheet 10 to a predetermined size of LED module, thereby remarkably lowering the cost of the process of preparing the color conversion sheet 10. At this time, when one color conversion sheet 10 covers at least two LED bare chips 25, the process cost may be further lowered.

On the other hand, the color conversion sheet 10 may include a first sheet 11 having a phosphor and a second sheet 12 having adhesiveness. However, as mentioned above, it is preferable that the color conversion sheet 10 does not include the second sheet when the underfilling layer 22a includes at least one of a UV-curable resin as a transparent adhesive component having adhesiveness, a thermosetting resin and a sealant. That is, it is possible for the underfilling layer 22a to function as an adhesive layer such as the second sheet 12 of the color conversion sheet 10.

Like the second embodiment of the present invention, when the underfilling layer 22a is formed, the heat generated from the LED bare chip 25 may be emitted more easily, and the color conversion sheet 10 may be more stably attached. Further, when the adhesive layer 12 of the color conversion sheet 10 functions as the underfilling layer 22a, a heat dissipation effect may be maximized while further reducing the processing steps.

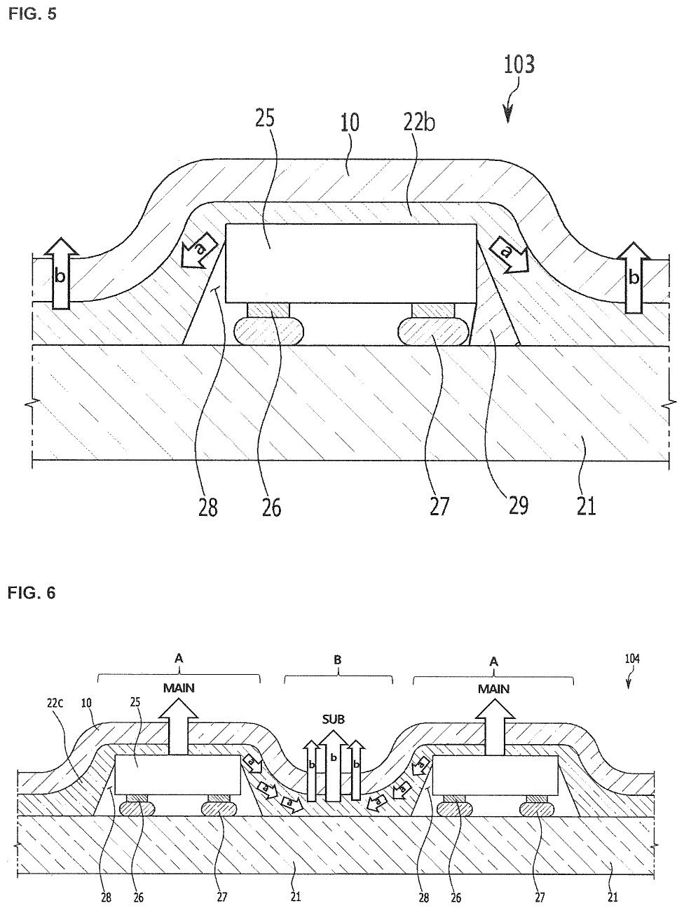

Hereinafter, a third embodiment of the present invention will be described. FIG. 5 is a cross-sectional view illustrating an LED module 103 according to a third embodiment of the present invention, and the same components as those of the first embodiment denote the same reference numerals and duplicated description of the same components is omitted.

In the third embodiment, the light diffusion adhesive layer 22b is formed to fill the space between the LED bare chips 25. The light diffusion adhesive layer 22b is preferably formed in a film shape having elasticity for firm adhesion with the color conversion sheet 10 to be described below. At this time, the light diffusion adhesive layer 22b is made of a light transmitting material that transmits light, and a surface where the light diffusion adhesive layer 22b contacts the substrate may be further applied with a white or silver material for reflecting light. However, the light diffusion adhesive layer 22b may be formed by injecting a liquid resin into the LED bare chips 25. At this time, the light diffusion adhesive layer 22b may be made of an epoxy resin or a polyimide resin.

The light diffusion adhesive layer 22b is formed to cover the side surface of the LED bare chip 25. More specifically, the light diffusion adhesive layer 22b may be formed to be in contact with the side surface of the LED bare chip 25. In FIG. 5, the light diffusion adhesive layer 22b may be formed to be in contact with a part of the side surface of the LED bare chip 25, but may also be formed to be in contact with the entire side surface of the LED bare chip 25. In this case, the light diffusion efficiency is further increased.

The light diffusion adhesive layer 22b may be disposed so as to cover the periphery of the LED bare chip 25 and be disposed to be slightly spaced apart from the side surface of the LED bare chip 25, and then may be in contact with the side surface of the LED bare chip 25 by compression.

Particularly, in the LED module according to the third embodiment, the light diffusion adhesive layer 22b emits emission light (direction a) of the LED bare chip 25 from the color conversion sheet 10 to an upper portion (direction b) of the region not corresponding to the LED bare chip. As a result, it is possible to significantly reduce the dot appearance phenomenon or shading of illumination which is a chronic problem of the LED illumination. That is, in recent years, a technique of inserting a lens for lateral light distribution has been developed. According to this embodiment, since the light diffusion adhesive layer 22b functions as a light guide plate, lateral light distribution is possible without insertion of an expensive lens, thereby improving the quality of the illumination and lowering the production cost.

Further, in the LED module 102 according to the third embodiment, the second sheet in the first embodiment may function as the light diffusion adhesive layer 22b. Thus, the process cost may be further reduced.

Further, the light diffusion adhesive layer 22b serves not only to planarize a surface where the color conversion sheet 10 is attached so that the color conversion sheet 10 may be stably installed on the substrate 21, but also to rapidly emit heat generated by the LED bare chip 25 and the substrate 21.

In the LED module 103 according to the third embodiment, the light diffusion adhesive layer 22b and the color conversion sheet 10 are integrally formed and attached in the direction of the LED bare chip 25 to manufacture an LED module. Accordingly, while the light diffusing adhesive layer 22b is formed to be in contact with the upper surface of the LED bare chip 25, a buffer space 28 is formed between the light diffusing adhesive layer 22b and the side surface of the LED bare chip 25. The buffer space 28 is formed to extend in a circumferential direction of the LED bare chip 25 and cover the side surface of the LED bare chip 25. In addition, the buffer space 28 may have a triangular channel shape and may have a triangular longitudinal section. According to the buffer space 28, the light emitted from the LED bare chip 25 is diffused in the buffer space 28, so that a dot appearance phenomenon may be further reduced.

When the light diffusing adhesive layer 22b and the color conversion sheet 10 are integrally formed and the strength for compressing the light diffusing adhesive layer 22b and the color conversion sheet 10 toward the LED bare chip 25 is further increased, a lead-in portion 29 in which the light diffusion adhesive layer 22b is led into the lower portion of the LED bare chip 25 may be generated. Since the lead-in portion 29 serves as a light guide plate for transmitting light emitted from the LED bare chip 25, the loss of light emitted from the LED bare chip 25 is further prevented, so that even if a diffusion effect of the buffer space is reduced, the amount of light emitted from the space between the bare chips is increased, thereby reducing the shading phenomenon.

Hereinafter, a fourth embodiment of the present invention will be described. FIG. 6 is a cross-sectional view illustrating an LED module 104 according to a fourth embodiment of the present invention, and the same components as those of the first embodiment denote the same reference numerals and duplicated description of the same components is omitted.

The LED module 104 according to the fourth embodiment of the present invention further includes a light diffusion layer 22c and is formed to fill a space between LED bare chips 25. At this time, it is preferable that the light diffusion layer 22c is formed to have a thickness larger than that of the light diffusion adhesive layer of the third embodiment so as to transmit more light.

The light diffusion layer 22c is preferably formed in a film shape having elasticity for firm adhesion with the color conversion sheet 10 to be described below. At this time, the light diffusion layer 22c is made of a light transmitting material that transmits light, and a surface where the light diffusion layer 22c contacts the substrate may be further applied with a white or silver material for reflecting light.

At this time, the light diffusion layer 22c is formed so as to cover the side surface of the LED bare chip 25 or to be in contact with the upper surface of the LED bare chip 25. At this time, the light diffusion layer 22c may also be formed to be in contact with the side surface of the LED bare chip 25. The light diffusion layer 22c may be disposed so as to cover the periphery of the LED bare chip 25 and be disposed to be slightly spaced apart from the side surface of the LED bare chip 25, and then may be in contact with the side surface of the LED bare chip 25 by compression.

Particularly, in the LED module according to the embodiment, the light diffusion layer 22c emits emission light (direction a) of the LED bare chip 25 from the color conversion sheet 10 to an upper portion (direction b) of the region not corresponding to the LED bare chip as illustrated in FIG. 6. That is, the region corresponding to the LED bare chip in the color conversion sheet 10 becomes a basic main light emitting region A, and the region not corresponding to the LED bare chip 25 forms a sub light emitting region B.

In the sub light emitting region B, the light initially emitted from the LED bare chip, reflected, and transmitted to the side, and the light emitted from the LED bare chip to the side are all reached, and as illustrated in FIG. 6, the lights are simultaneously reached from the covering LED bare chips, thereby realizing a light flux similar to the main light emitting region A. As a result, it is possible to significantly reduce the dot appearance phenomenon or shading of illumination which is a chronic problem of the LED illumination.

Further, the light diffusion layer 22c serves not only to planarize a surface where the color conversion sheet 10 is attached so that the color conversion sheet 10 may be stably installed on the substrate 21, but also to rapidly emit heat generated by the LED bare chip 25 and the substrate 21.

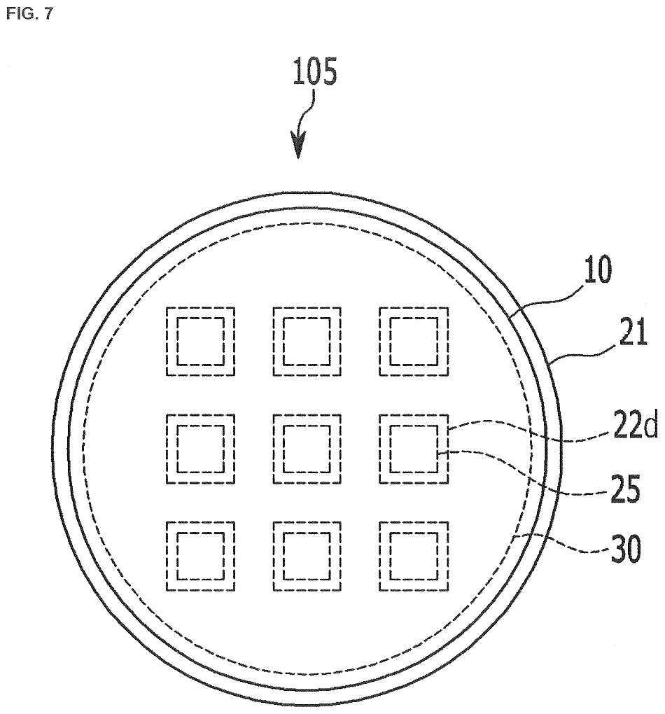

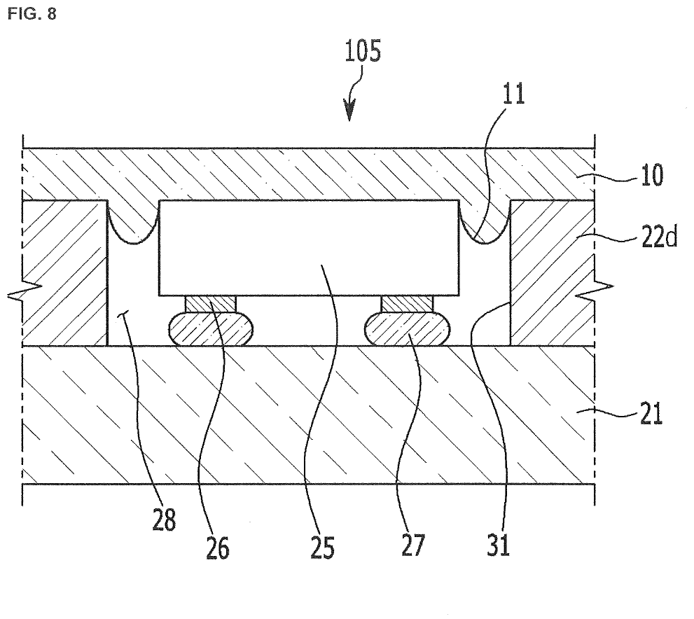

Hereinafter, a fifth embodiment of the present invention will be described. FIG. 7 is a plan view illustrating an LED module according to a fifth embodiment of the present invention and FIG. 8 is a cross-sectional view illustrating the LED module according to the fifth embodiment of the present invention. At this time, the same components as those of the first embodiment denote the same reference numerals, and duplicated description of the same components is omitted.

An LED module 105 according to the fifth embodiment of the present invention includes a sheet block 22d. The sheet block 22d is formed so as to fill a space between LED bare chips 25. At this time, the sheet block 22d may be integrally formed or a plurality of sheet blocks may be formed to be attached so as to fill a space between the LED bare chips. The sheet block 22d is preferably formed in a film shape having elasticity for firm adhesion with a color conversion sheet 10 to be described below. At this time, the sheet block 22d is made of a light transmitting material that transmits light, and a surface where the sheet block 22d contacts the substrate may be further applied with a white or silver material for reflecting light.

The sheet block 22d may also be made of at least one of a UV curable resin as a transparent adhesive component, a thermosetting resin, and a sealant. However, it is needless to say that the present invention is not limited to any one material. The sheet block 22d serves to transmit the light emitted by the LED bare chip 25 to a region where the color conversion sheet 10 does not correspond to the LED bare chip.

At this time, the sheet block 22d is formed so as to cover the side surface of the LED bare chip 25 or to be in contact with the upper surface of the LED bare chip 25. At this time, since the seat block 22d is attached to the LED bare chip 25 so as to be spaced apart from the LED bare chip 25, a gap region 28 is formed between the sheet block and the LED bare chip. At this time, a light scattering surface 31 is formed on one surface of the sheet block constituting the gap region 28. The light scattering surface 31 has an irregular surface roughness. Accordingly, since the light transmitted to the sheet block 31 is scattered and transmitted, a color rendering property of the light excited and emitted from the color conversion sheet 10 (light emitted from a portion not corresponding to the LED bare chip) is further improved.

The light initially emitted to the upper portion of the LED bare chip, reflected by the sheet block to be transmitted and reached to the side surface implements a similar luminous flux to the light initially emitted from the side of the LED bare chip, reaching a region between the LED bare chips, and reaching the region between the covering LED bare chips to be emitted to the upper side of the LED bare chip. As a result, it is possible to improve the color rendering property and significantly reduce the dot appearance phenomenon or shading of illumination which is a chronic problem of the LED illumination.

Further, the sheet block 22d serves not only to planarize a surface where the color conversion sheet 10 is attached so that the color conversion sheet 10 may be stably installed on the substrate 21, but also to rapidly emit heat generated by the LED bare chip 25 and the substrate 21.

In the LED module according to the fifth embodiment, the color conversion sheet 10 is compressed on the substrate in the direction of the LED bare chip 25, so that a protrusion 11 is formed in the gap region 28. At this time, the upper surface of the sheet block 22d has a region formed to be equal to or lower than the upper surface of the LED bare chip 25 by such compressing. In other words, the region corresponding to the LED bare chip protrudes relatively upward, and the region not corresponding to the LED bare chip may be formed so that concave and convex patterns relatively downward are alternately shown. When the protrusion 11 is formed, the color conversion sheet 10 may be attached more stably and the plurality of LED bare chips 25 may emit white light by one color conversion sheet 10.

Further, the light emitted from the side surface of the LED bare chip is reflected by the protrusion 11 to be more easily transmitted to the sheet block 22d. Therefore, there is an effect that the shading is further prevented.

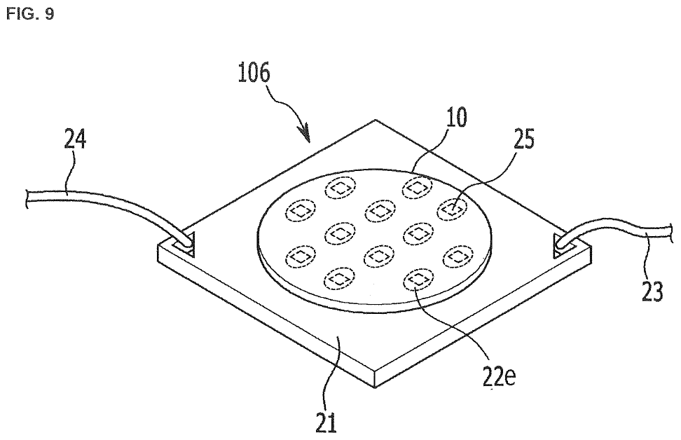

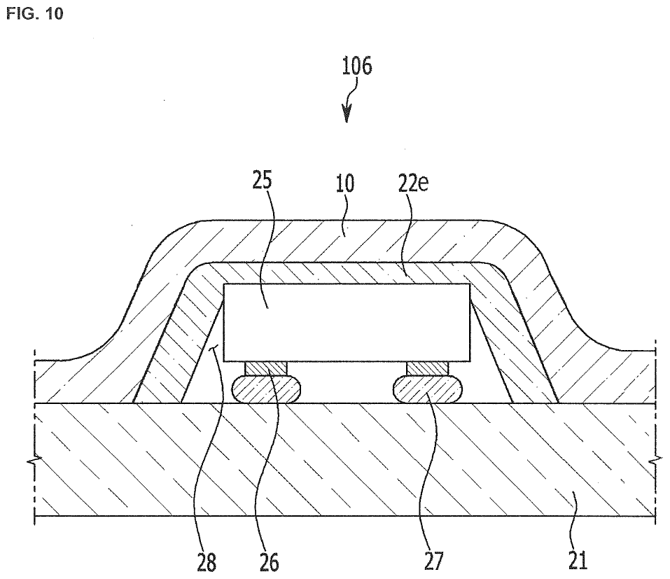

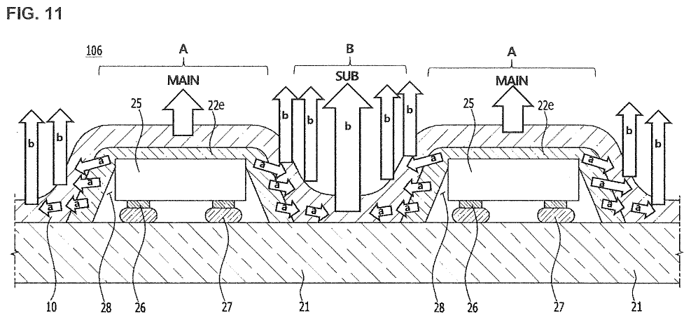

Hereinafter, a sixth embodiment of the present invention will be described. FIG. 9 is a perspective view illustrating an LED module according to a sixth embodiment of the present invention, FIG. 10 is a cross-sectional view illustrating the LED module according to the sixth embodiment of the present invention, and FIG. 11 is a cross-sectional view illustrating an operation of the LED module according to the sixth embodiment of the present invention. At this time, the same components as those of the first embodiment denote the same reference numerals, and duplicated description of the same components is omitted.

An LED module 106 according to the sixth embodiment of the present invention includes a substrate 21, an LED bare chip 25, a light diffusion lens 22e, and a color conversion sheet 10.

The light diffusion lens 20 may be formed using materials such as acrylic, polycarbonate, silicone, and PET excellent in light transmittance and excellent in moldability, and the light diffusion lens 20 is formed adjacent to the side surface of the LED bare chips 25 for lateral transmission of light. That is, the LED generally has a directional angle width that has an increased amount of light emitted toward the upper side, and it is necessary to adjust an irradiation range of the light by using an additional lens for lateral transmission of light. At this time, it is preferable that the light diffusion lens 22e is formed in a combination of a concave lens or a convex lens having a focal length within a set range.

Referring to FIG. 10, the light diffusion lens 22e may be formed adjacent to the side surface of the LED bare chip 25 or may be formed to contact the side surface or the upper surface of the LED bare chip 25 to transmit the light to a side region spaced apart from the LED bare chip 25. However, as illustrated in FIG. 10, the light diffusion lens 22e may form a buffer space 28 that is not in contact with the side surface of the LED bare chip 25. The buffer space 28 may have a triangular channel shape and may have a triangular longitudinal section. According to the buffer space 28, the light emitted from the LED bare chip 25 is diffused in the buffer space 28 and then enters the light diffusing lens 22e, thereby further enhancing the lateral transmission efficiency of light and further reducing the shading.

The color conversion sheet 10 is a sheet including a phosphor and is attached on the substrate 21 or on the light diffusion lens 22e so as to cover at least one LED bare chip 25. More specifically, the color conversion sheet 10 may be attached to the upper surface of the light diffusion lens 22e or the substrate 21. At least one color conversion sheet 10 may be installed on the substrate 21 so as to cover all the LED bare chips 25 provided on the substrate 21.

On the other hand, the color conversion sheet 10 serves to excite and emit the light transmitted to the side surface by the light diffusion lens 22e, or transmit and emit the light transmitted to the side surface by the light diffusion lens 22e to the side surface. As a result, the light is emitted even in regions not corresponding to the LED bare chip 25 and the light diffusion lens 22e.

Hereinafter, an operation of the LED module 106 according to the sixth embodiment of the present invention will be described. Referring to FIG. 11, in the LED module 106 according to the sixth embodiment of the present invention, a region where the LED bare chip 25 and the light diffusion lens 22e forms a main light emitting region A and other regions form a sub light emitting region B. That is, the light diffusion lens 22e transmits the light emitted from the LED bare chip 25 to the side surface (direction a) and transmits the light to the color conversion sheet 10, and the light is emitted or further transmitted to the side surface again to be evenly distributed in a space between the bare chips 25.

That is, the sub light emitting region B forms a light emitting region in which the light emitted upward by the LED bare chip 25, reflected, and transmitted and reached to the side surface, the light emitted to the side surface by the LED bare chip 25, the light transmitted to the side surface by the light diffusion lens 22e, and the light transmitted by the three types and then moving to the color conversion sheet 10 again to be reached are excited and the emitted (direction b).

At this time, since the light emitted from the covering LED bare chips reaches the sub light emitting region B at the same time, a light flux similar to the main light emitting region A is implemented, thereby significantly reducing the shading. In addition, in the LED module according to the embodiment of the present invention, the light initially emitted from the LED bare chip 25 moves to the side surface before being excited by the phosphor included in the color conversion sheet 10 and is finally excited by the color conversion sheet 10 to be emitted. Therefore, it is possible to implement a high-quality LED module for illumination without deteriorating the color rendering property of the light.

As described above, preferred embodiments of the present disclosure have been disclosed in the present disclosure and the drawing and although specific terminologies are used, but they are used in a general meaning for easily describe the technical content of the present disclosure and help understanding the present disclosure and are not limited to the scope of the present disclosure. In addition to the embodiments disclosed herein, it is apparent to those skilled in the art that other modified examples based on the technical spirit of the present invention can be executed.

### EXPLANATION OF NUMERAL REFERENCES AND SYMBOLS

101,102,103,104,105,106: LED module
10: Color conversion sheet
11: First sheet
12: Second sheet
22a: Underfilling layer
22b: Light diffusion adhesive layer
22c: Light diffusion layer
22d: Sheet block
22e: Light diffusion lens
23: First wire
24: Second wire
25: LED bare chip
26: Terminal
27: Shouldering portion

1. An LED module comprising:
a substrate;
at least one LED bare chip mounted on the substrate; and
at least one color conversion sheet formed on the LED bare chip and including a phosphor,
wherein the color conversion sheet is formed so as to cover at least one LED bare chip and a height of a region corresponding to the LED bare chip in the color conversion sheet is different from a height of a region not corresponding to the LED bare chip in the color conversion sheet.

2. The LED module of claim 1, further comprising:
at least one underfilling layer formed to fill a space between the LED bare chips on the substrate and cover the periphery of the LED bare chip.

3. The LED module of claim 2, wherein the color conversion sheet is attached to an upper surface of the underfilling layer or an upper surface of the LED bare chip.

4. The LED module of claim 1, wherein the color conversion sheet is formed so that the region corresponding to the LED bare chip protrudes upward from the region not corresponding to the LED bare chip.

5. The LED module of claim 1, further comprising:
at least one light diffusion adhesive layer formed to fill a space between the LED bare chips on the substrate and to cover the side surface of the LED bare chip or contact the upper surface of the LED bare chip,
wherein a buffer space or a lead-in portion in which the light diffusion adhesive layer is led into the lower portion of the LED bare chip is formed between the color conversion sheet and the side surface of the LED bare chip.

6. The LED module of claim 1, wherein the buffer space is formed between the color conversion sheet and the side surface of the LED bare chip.

7. The LED module of claim 6, wherein the buffer space is formed by compressing the color conversion sheet onto the substrate.

8. The LED module of claim 1, further comprising:
a light diffusion layer formed to fill a space between the LED bare chips on the substrate and formed to cover the side surface of the LED chip or contact the upper surface of the LED bare chip,
wherein the light diffusion layer transmits the light emitted from the LED bare chip to a region which the color conversion sheet does not correspond to the LED bare chip.

9. The LED module of claim 1, further comprising:
at least one sheet block formed to fill a space between the LED bare chips on the substrate,
wherein a gap region is formed between the sheet block and the LED bare chip.

10. The LED module of claim 1, wherein a region of the color conversion sheet corresponding to the gap region is formed with a protrusion inserted into the gap region.

11. The LED module of claim 1, further comprising:
a light diffusion lens formed adjacent to the side surface of the LED bare chip on the substrate,
wherein in the color conversion sheet, the region corresponding to the LED bare chip and the region corresponding to the light diffusion lens form a main light emitting region, and the regions not corresponding to the LED bare chip and the light diffusion lens forms a sub light emitting region in which light reached by the light diffusion lens is excited and emitted or moves into the color conversion sheet to be excited and emitted.
